(19) United States
(12) Patent Application Publication
(10) Pub. No.: US 2024/0247018 A1
(43) Pub. Date: Jul. 25, 2024

(54) HETEROCYCLIC MODIFIED PLATINUM COMPLEX CONTAINING ONCN TETRADENTATE LIGAND

(71) Applicant: GUANGDONG AGLAIA OPTOELECTRONIC MATERIALS CO., LTD., Foshan, Guangdong (CN)

(72) Inventors: Xinwei WU, Foshan (CN); Wenping XIAO, Foshan (CN); Lei DAI, Foshan (CN); Lifei CAI, Foshan (CN)

(73) Assignee: GUANGDONG AGLAIA OPTOELECTRONIC MATERIALS CO., LTD., Foshan, Guangdong (CN)

(21) Appl. No.: 18/562,177

(22) PCT Filed: Feb. 26, 2022
(86) PCT No.: PCT/CN2022/078118

§ 371 Date: Nov. 17, 2023

(30) Foreign Application Priority Data
Jun. 17, 2021 (CN) 202110673530.2

(51) Int. Cl. C07F 15/00; H10K 85/30

(52) U.S. Cl. CPC C07F 15/0086; H10K 85/346

(57) ABSTRACT

The present invention relates to a heterocyclic modified platinum complex containing an ONCN tetradentate ligand, which has a structure as shown in Chemical Formula (I). The complex is used in organic light-emitting diodes, has a relatively low driving voltage and relatively high luminous efficiency, can significantly prolong the service life of a device, and has the potential for application in the field of organic electroluminescent devices. The present invention further provides an organic electroluminescent device including a cathode, an anode and an organic layer, the organic layer includes one or more layers of a hole injection layer, a hole transport layer, a light-emitting layer, a hole blocking layer, an electron transport layer and an electron injection layer, and at least one layer in the organic layer contains the compound as shown in Structural Formula (I).

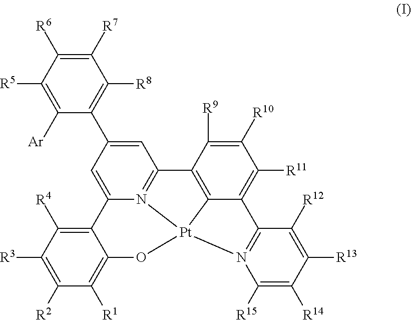

### TECHNICAL FIELD

The present invention relates to the field of luminescent materials, and specifically relates to a platinum complex containing a heterocyclic ring and application thereof in an organic light-emitting diode.

### BACKGROUND

Due to various advantages, such as ultralight weight, ultrathin volume, low power consumption, autonomous luminescence, large operating temperature range, wide color gamut, wide viewing angle, high response speed, and easiness in flexible display, phosphorescent organic light-emitting diodes (OLEDs) have attracted great attention in the academic world and the industry in the past decades. As for phosphorescent OLED molecules, high synthetic diversity is provided by coordination between transition metal centers and organic frameworks. On the basis of changes in properties of the metal centers, bonding modes of metal complexation and design of ligands, representative building block compounds are formed. Through reasonable design of multifunctional metal complexes, not only can electron absorption, luminescence and redox properties in an excited state be regulated, but also diversified optical functional properties can be achieved. The OLEDs have become a new-generation display and a solid-state lighting technology with a great application prospect.

Since the phosphorescent OLEDs were discovered in 1998, an internal quantum efficiency of 100% can be achieved theoretically as the phosphorescent OLEDs can efficiently utilize singlet and triplet excitons for luminescence compared with traditional fluorescent OLEDs. Thus, a commercialization process of the OLEDs is promoted to a large extent. Most of metal complexes are developed based on hexadentate complexes with Ir (III) as a metal core.

According to recent development of the metal complexes in the last decade, square planar Pt (II) and Pd (II) complexes even have better properties than Ir complexes in many respects. In particular, N-heterocyclic carbinyl emitters and tetradentate cyclic metallized Pt and Pd complexes are developed, thereby significantly improving the light emission efficiency, reducing exciton radiation lifetime and having higher competition with the Ir complexes. In addition, due to unique and diverse molecular design of these complexes, a narrower emission spectrum can be obtained, and fine adjustment of various photophysical properties, such as photoluminescence (PL), highest occupied molecular orbital (HOMO), lowest unoccupied molecular orbital (LUMO), CIE and T3 energy levels, with different substituents can be realized. Meanwhile, although the iridium complexes are most common luminescent materials in the OLEDs at present, the metal iridium is an element with the lowest relative content in the earth's crust, and on the contrary, platinum and palladium, which are heavy metals, have much higher reserves in the earth's crust.

Bidentate and tridentate ligands containing nitrogen atoms or carbon donors, such as C\hat{ }N, C\hat{ }N and N\hat{ }C\hat{ }N systems, are usually used for developing phosphorescent platinum complexes. When these ligands are used for synthesizing complexes with d8 electron configurations, the form of “a tridentate ligand and a monodentate ligand” or the form of “two bidentate ligands” is usually selected. As for ONCN-based Pt (II) tetradentate complexes, metal ions are stabilized in centers of the complexes due to a chelation effect of polydentate ligands, and demetallization of common complexes can be inhibited, so that such complexes have high thermal stability and relatively high chemical stability. A dx2-y2 orbital energy level of metal ions is increased due to the presence of strong field ligands, so that molecular deformation in an excited state is weakened, and the luminous quantum efficiency is expected to be improved. Covalent metal-carbon bonds increase the mixing of metal d orbitals and ligand orbitals, thereby also improving the stability of compounds. The mixing of metal d orbitals and ligand orbitals can enhance the impact of the metal centers on an excited state of the ligands and enhance a spin-orbit coupling effect, thereby increasing the quantum yield in a triplet state and promoting efficient phosphorescent radiation.

Although the ONCN-based Pt (II) tetradentate complexes have many advantages, Pt metal complex luminescent materials have been infinitely used in the industry. However, properties, such as the luminous efficiency and the service life, of the OLEDs, still need to be further improved so as to meet demands of commercial production in a large scale.

### SUMMARY

Based on the demands in the above fields, the present invention provides a heterocyclic modified platinum complex containing an ONCN tetradentate ligand, and the luminous intensity and luminous efficiency of the platinum complex in specific optical components can be significantly improved by modification of a nitrogen-containing heterocyclic structure of the platinum complex.

A heterocyclic modified platinum complex containing an ONCN tetradentate ligand has a structure as shown in Formula (I):

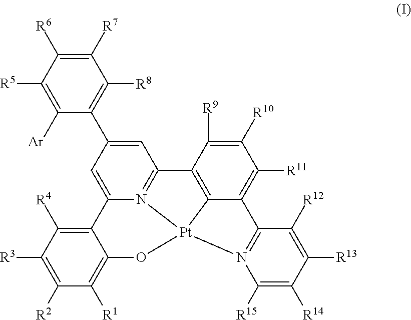

where
R¹ to R¹⁵ are independently selected from hydrogen, deuterium, halogen, amino, carbonyl, carboxyl, alkylthio, cyano, sulfonyl, phosphino, substituted or unsubstituted alkyl containing 1-20 carbon atoms, substituted or unsubstituted cycloalkyl containing 3-20 cyclic carbon atoms, substituted or unsubstituted alkenyl containing 2-20 carbon atoms, and substituted or unsubstituted alkoxyl containing 1-20 carbon atoms;
Ar is selected from substituted or unsubstituted aryl containing 6-30 carbon atoms, and substituted or unsubstituted heteroaryl containing 3-30 carbon atoms; the heteroaryl includes one or more of N, S and O heteroatoms;
and the “substituted” refers to substitution with halogen, amino, cyano, C₁-C₄ alkyl, or fluorinated C₁-C₄ alkyl.

Optionally, the R¹ to R¹⁵ are independently selected from hydrogen, deuterium, halogen, amino, alkylthio, cyano, substituted or unsubstituted alkyl containing 1-6 carbon atoms, substituted or unsubstituted cycloalkyl containing 3-6 cyclic carbon atoms, substituted or unsubstituted alkenyl containing 2-6 carbon atoms, and substituted or unsubstituted alkoxyl containing 1-6 carbon atoms;
the Ar is selected from substituted or unsubstituted aryl containing 6-30 carbon atoms, and substituted or unsubstituted heteroaryl containing 3-30 carbon atoms;
and the “substituted” refers to substitution with halogen, amino, cyano, C₁-C₄ alkyl, or fluorinated C₁-C₄ alkyl.

Optionally, the R¹ to R¹⁵ are independently selected from hydrogen, deuterium, halogen, cyano, C₁-C₄ alkyl, and substituted or unsubstituted cycloalkyl containing 3-6 cyclic carbon atoms;
the Ar is selected from substituted or unsubstituted aryl containing 6-30 carbon atoms, and substituted or unsubstituted heteroaryl containing 3-30 carbon atoms;
and the “substituted” refers to substitution with halogen, amino, cyano, C₁-C₄ alkyl, or fluorinated C₁-C₄ alkyl.

Optionally, the R¹ to R¹⁵ are independently selected from hydrogen, deuterium, cyano, methyl, isopropyl, isobutyl, tert-butyl, substituted or unsubstituted cyclopentyl, and substituted or unsubstituted cyclohexyl;
the Ar is selected from substituted or unsubstituted phenyl, substituted or unsubstituted pyridinyl, substituted or unsubstituted pyrazinyl, substituted or unsubstituted pyrimidinyl, substituted or unsubstituted imidazolyl, and substituted or unsubstituted carbazolyl;
and the “substituted” refers to substitution with halogen, cyano, C₁-C₄ alkyl, or fluorinated C₁-C₄ alkyl.

Optionally, in General Formula (I), the R¹ to R¹⁵ are independently selected from hydrogen, deuterium, methyl, tert-butyl, and cyano;
the Ar is selected from substituted or unsubstituted phenyl, substituted or unsubstituted pyridinyl, substituted or unsubstituted imidazolyl, and substituted or unsubstituted carbazolyl;
and the “substituted” refers to substitution with halogen, amino, cyano, C₁-C₄ alkyl, or fluorinated C₁-C₄ alkyl.

Further optionally, in General Formula (I), the R¹³ in the R¹ to R¹⁵ is tert-butyl, and other groups are hydrogen;
and the Ar is selected from substituted or unsubstituted phenyl, substituted or unsubstituted pyridinyl, or substituted or unsubstituted carbazolyl.

Examples of the metallic platinum complex of the present invention are listed below hut are not limited to the structures listed.

| | |
|---|---|
| 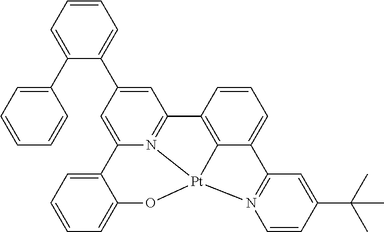 | 1 |
| 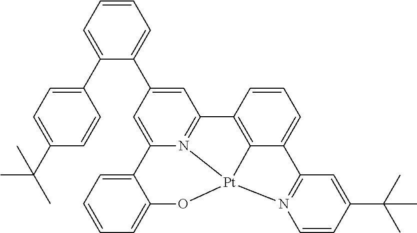 | 2 |
| 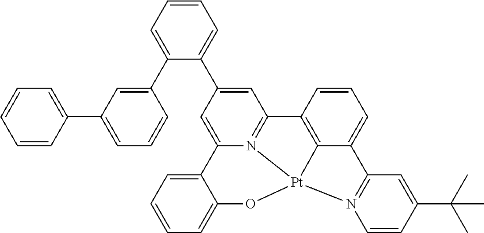 | 3 |
| 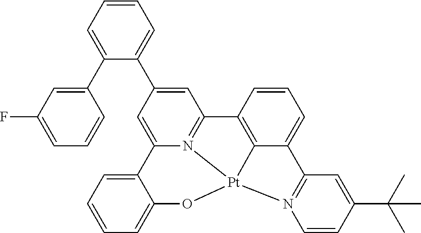 | 4 |
| 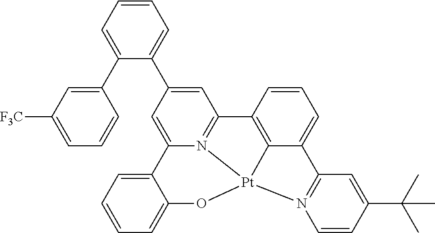 | 5 |
| 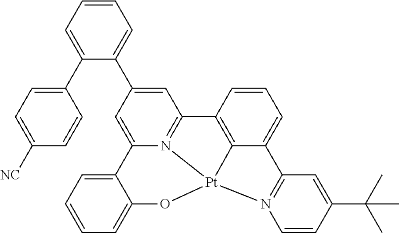 | 6 |
| 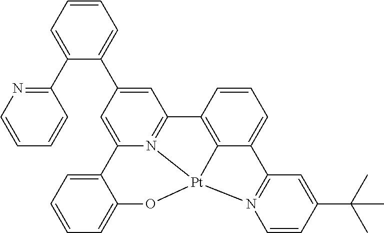 | 7 |
| 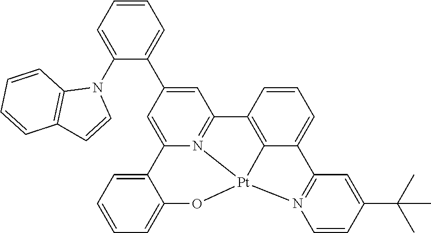 | 8 |
| 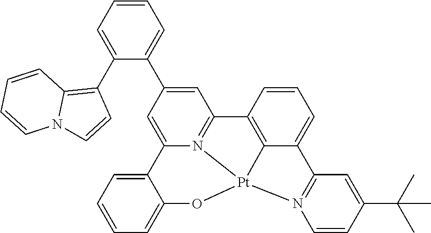 | 9 |
| 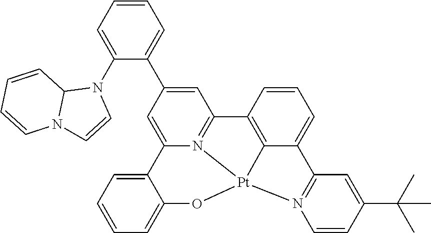 | 10 |
| 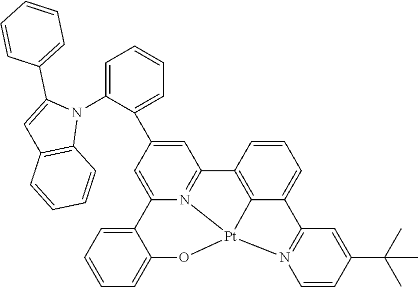 | 11 |
| 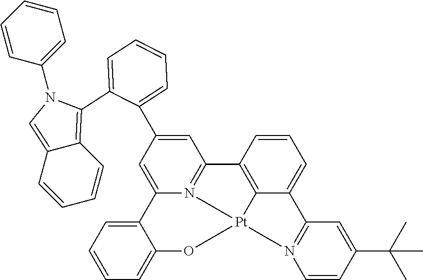 | 12 |
| 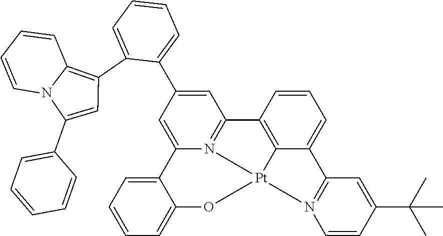 | 13 |
| 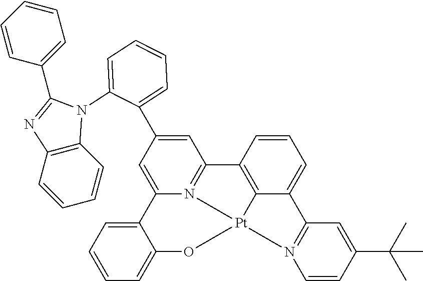 | 14 |
| 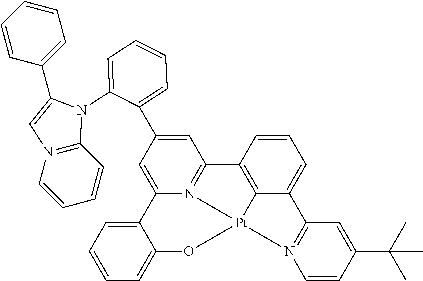 | 15 |
| 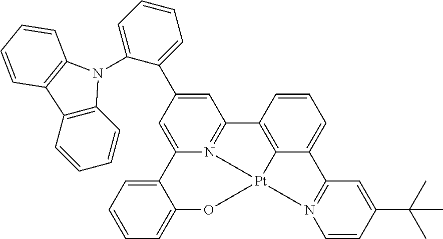 | 16 |
| 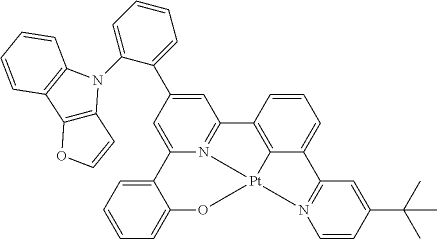 | 17 |
| 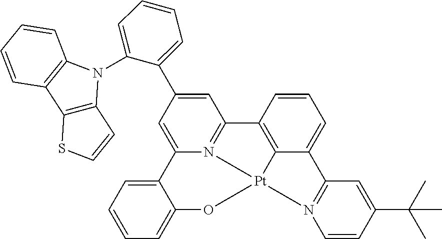 | 18 |
| 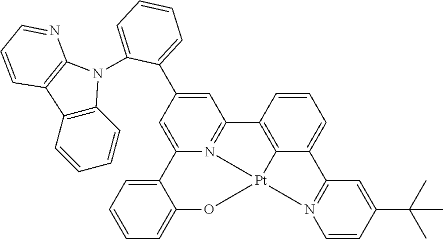 | 19 |
| 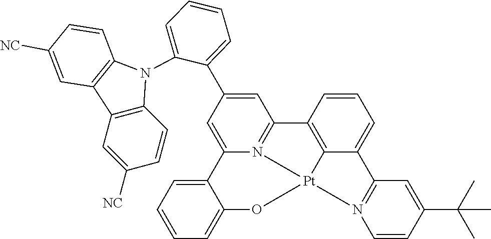 | 20 |
| 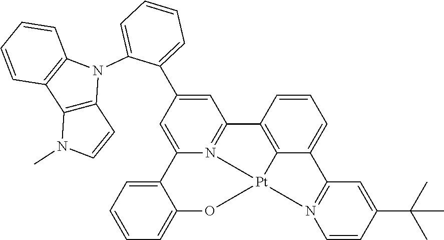 | 21 |
| 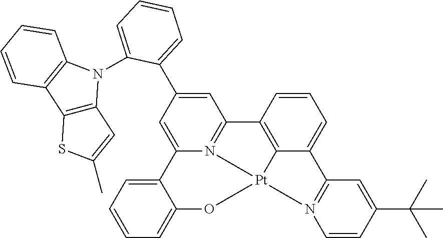 | 22 |
| 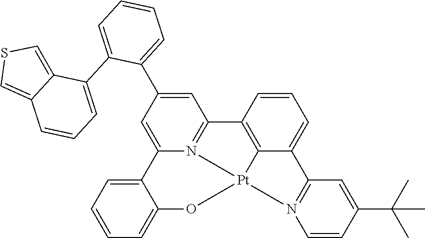 | 23 |
| 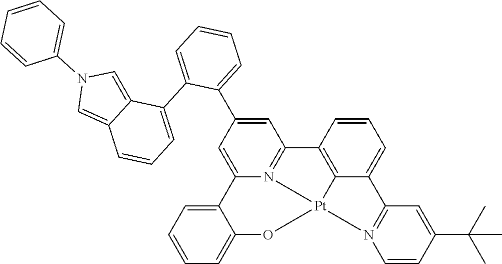 | 24 |
| 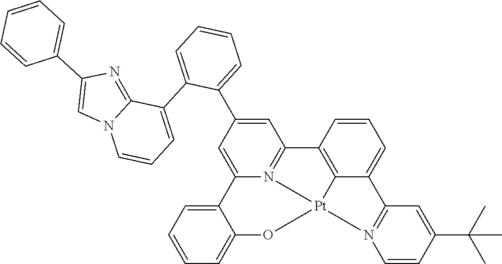 | 25 |
| 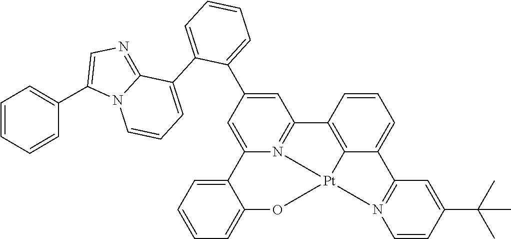 | 26 |
| 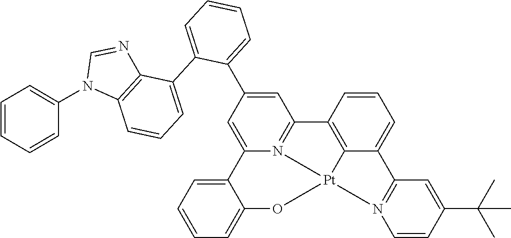 | 27 |
| 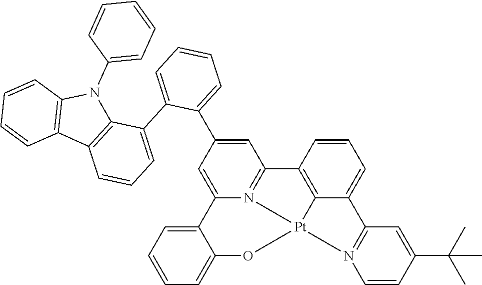 | 28 |
| 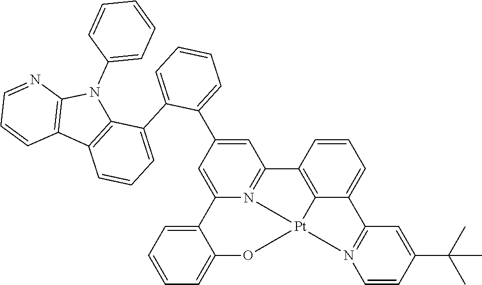 | 29 |
| 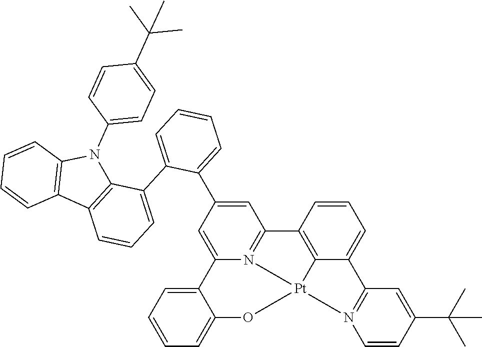 | 30 |
| 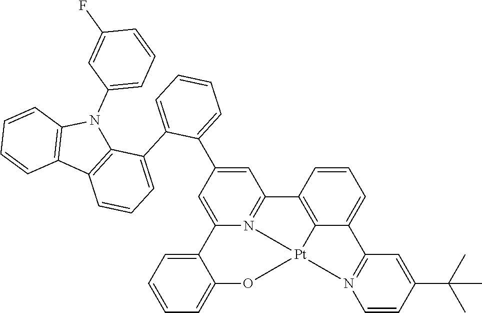 | 31 |
| 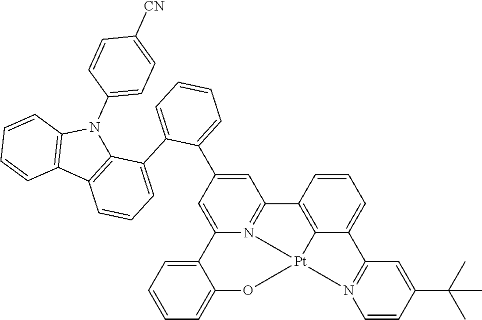 | 32 |
| 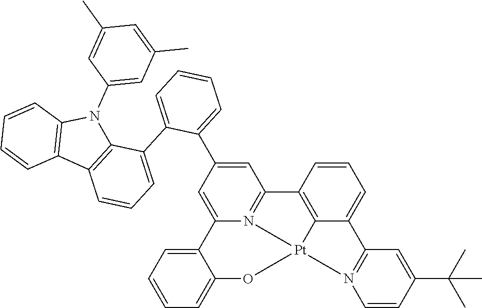 | 33 |
| 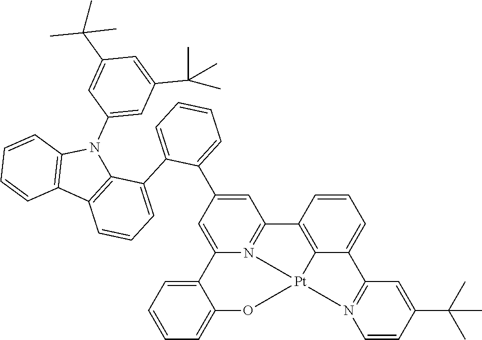 | 34 |
| 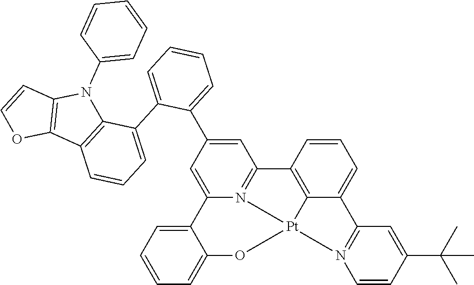 | 35 |
| 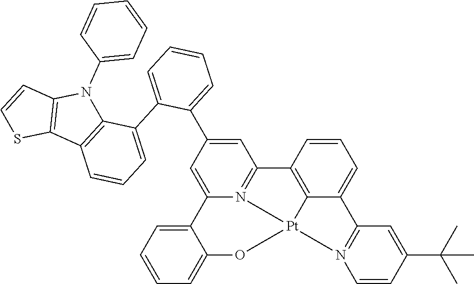 | 36 |
| 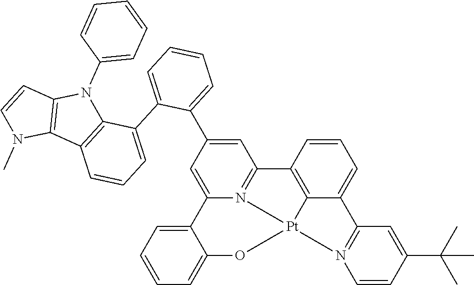 | 37 |
| 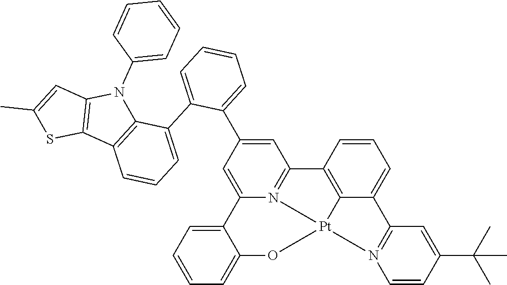 | 38 |
| 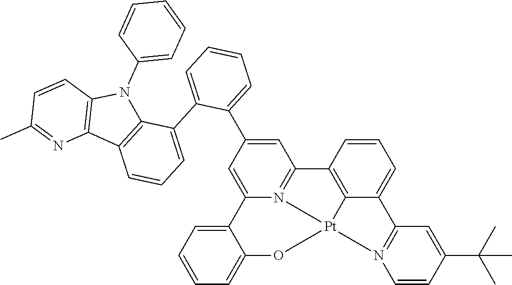 | 39 |
| 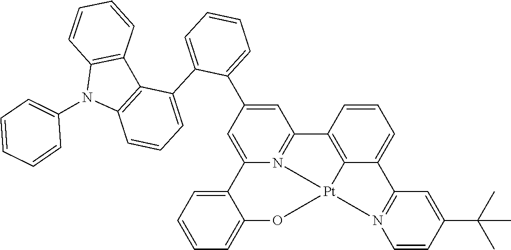 | 40 |
| 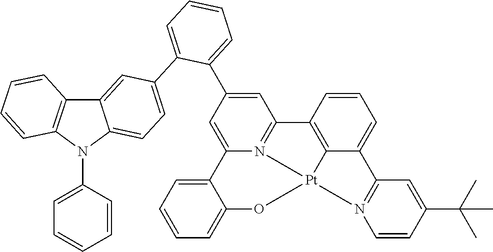 | 41 |
| 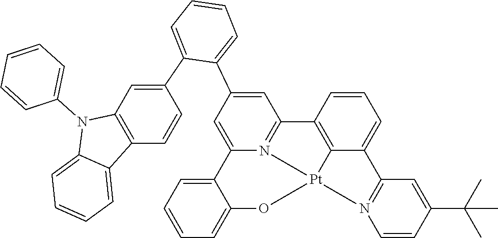 | 42 |
| 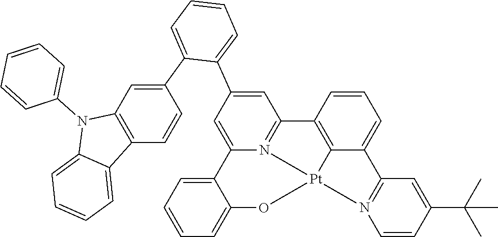 | 43 |

A precursor of the metal complex, namely, a ligand, has a structural formula below:

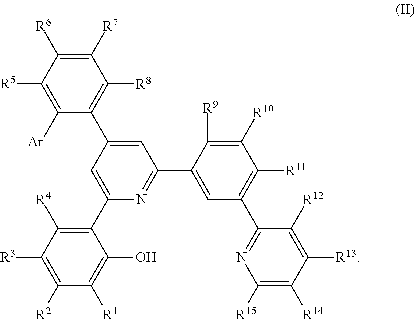

Application of the platinum complex in an organic light-emitting diode, an organic thin film transistor, an organic photovoltaic device, a light-emitting electrochemical cell, or a chemical sensor is provided.

An organic light-emitting diode includes a cathode, an anode and an organic layer, the organic layer includes one or more layers of a hole injection layer, a hole transport layer, a light-emitting layer, a hole blocking layer, an electron injection layer and an electron transport layer, and the organic layer contains the platinum complex.

Optionally, the platinum complex is located in the light-emitting layer.

According to an ONCN-based platinum ligand skeleton of the present invention, the electroluminescence performance of a material is improved by adding a modification structure.

The compound has simple synthesis steps and an easily mature technology.

Compared with conventional organic electroluminescent compounds, the compound has higher electrophosphorescent photoelectron yield and lower exciton radiation attenuation lifetime.

The luminous intensity and luminous efficiency of the compound in specific optical components can be significantly improved by modification of a nitrogen-containing heterocyclic structure of the compound.

The structure has many modifiable sites, and steric hindrance increased by a carbazolyl group contained can effectively reduce an aggregation effect between molecules.

Spatial configurations of molecules and process preparation properties of molecules can be improved by connecting functional groups at different sites of the compound.

Device results show that the platinum complex material of the present invention has a lower driving voltage and higher luminous efficiency when applied to an organic light-emitting diode. In addition, an organic light-emitting diode based on the complex of the present invention has obviously better device life than complex materials in comparative examples, which can meet requirements of the display industry for luminescent materials and has a good industrialization prospect.

### BRIEF DESCRIPTION OF DRAWINGS

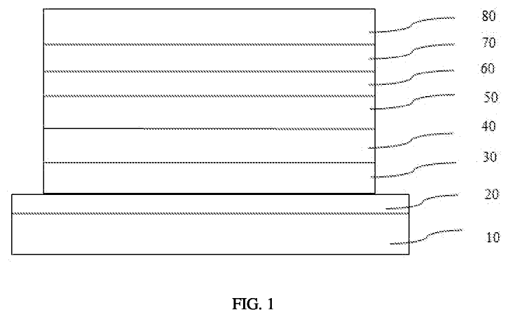

FIG. 1 is a structural diagram of an organic light-emitting diode device of the present invention,
where 10 represents a glass substrate, 20 represents an anode, 30 represents a hole injection layer, 40 represents a hole transport layer, 50 represents a light-emitting layer, 60 represents an electron transport layer, 70 represents an electron injection layer, and 80 represents a cathode.

### DETAILED DESCRIPTION OF EMBODIMENTS

The present invention has no requirements for synthetic methods of materials. In order to describe the present invention in more detail, the following examples are provided, but the present invention is not limited thereto. Unless otherwise specified, raw materials used in the following synthesis processes are commercially available products.

### Example 1: Synthesis of a Complex 1

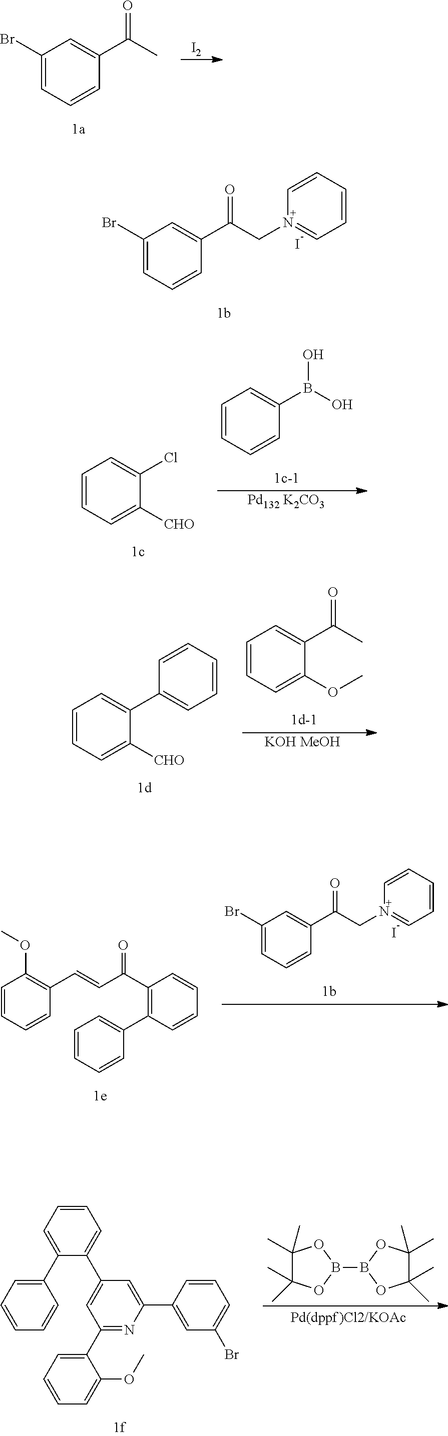

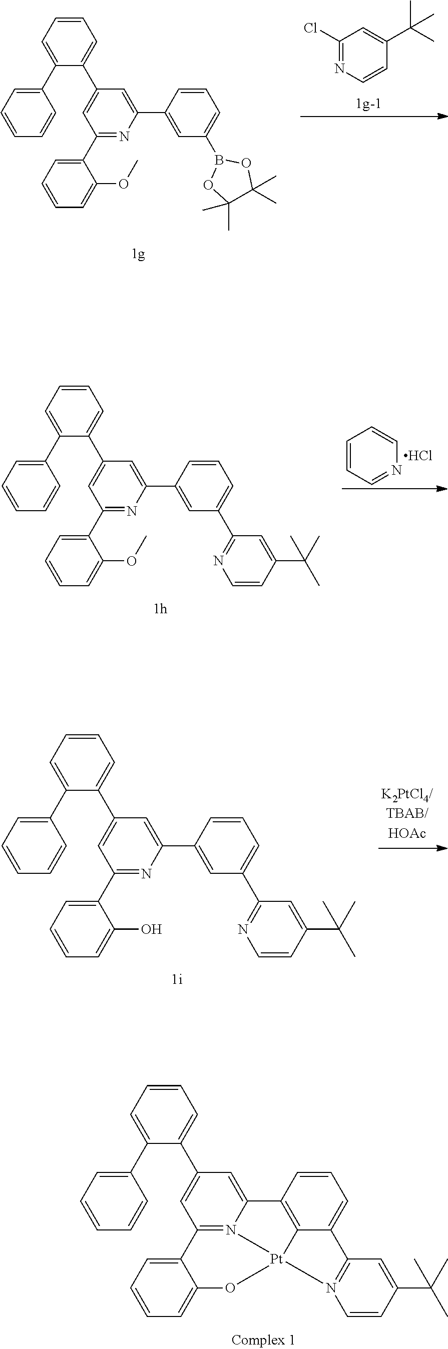

### Synthesis of a Compound 1b

A compound 1a (30.0 g, 0.15 mol) and I₂ (39.0 g, 0.15 mol) were dissolved in pyridine (200 mL) in a 500 ml one-necked flask, and the above compounds were heated to 120° C. and stirred overnight under the protection of nitrogen. A resulting reaction solution was cooled to room temperature and subjected to suction filtration to obtain a brown solid. Then, the solid was hot beaten with methanol for 1 hour and filtered to obtain 44.0 g of a light yellow solid compound 1b with a yield of 72%.

H NMR (400 MHZ, DMSO) δ 8.97 (d, J=5.6 Hz, 2H), 8.74 (t, J=7.8 Hz, 1H), 8.33-8.25 (m, 2H), 8.19 (s, 1H), 8.04 (d, J=7.8 Hz, 1H), 7.99 (d, J=8.0 Hz, 1H), 7.62 (t, J=7.9 Hz, 1H), 6.48 (s, 2H).

### Synthesis of a Compound 1d

A compound 1c (20 g, 142.28 mmol), a compound 1C-1 (19.08 g, 156.51 mmol), Pd₁₃₂ (1.5 g, 2.11 mmol) and potassium carbonate (58.99 g, 426.84 mmol) were added into dioxane (200 ml) and water (50 ml) in a 500 ml one-necked flask. Stirring was performed to carry out a reaction at 80° C. for 2 hours under the protection of nitrogen. After cooling was performed to room temperature, water and dichloromethane were added to perform extraction for two times. Then, organic phases were combined and spin-dried for removing a solvent, and a residue was separated by column chromatography with a mixed solvent including ethyl acetate and n-hexane at a ratio of 1:100 to obtain 14.4 g of a white solid with a yield of 55.54%.

¹H NMR (400 MHz, Chloroform-d) δ 9.99 (s, 1H), 8.06-8.02 (m, 1H), 7.61 (td, J=7.5, 1.4 Hz, 1H), 7.52-7.30 (m, 7H).

### Synthesis of a Compound 1e

The compound 1d (20 g, 109.76 mmol) and a compound 1d-1 (19.98 g, 99.78 mmol) were added into methanol (150 ml) in a 500 ml three-necked flask, and the above compounds were heated to 47° C. to carry out a reaction under the protection of nitrogen. An alkali solution prepared with potassium hydroxide (27.99 g, 498.90 mmol) and water (38 ml) was added into the three-necked flask, which was completely dropped within 0.5 hour. Stirring was performed to carry out a reaction for 2 hours. After cooling was performed to room temperature, water and dichloromethane were added to perform extraction for two times. Then, organic phases were combined and spin-dried for removing a solvent, and a residue was separated by column chromatography with a mixed solvent including ethyl acetate and n-hexane at a ratio of 1:20 to obtain 27.78 g of a yellow liquid with a yield of 81.7%.

¹H NMR (400 MHz, Chloroform-d) δ 7.84-7.79 (m, 1H), 7.68 (d, J=15.9 Hz, 1H), 7.56 (dd, J=7.6, 1.6 Hz, 1H), 7.50-7.27 (m, 10H), 7.02-6.92 (m, 2H), 3.86 (s, 3H).

### Synthesis of a Compound 1f

The compound 1e (27.3 g, 86.83 mmol), the compound 1b (35.06 g, 86.83 mmol) and ammonium acetate (58.66 g, 0.78 mol) were added to acetic acid (196 ml) in a 500 ml one-necked flask. Stirring was performed to carry out a reaction at 120° C. for 2 hours under the protection of nitrogen. After cooling was performed to room temperature, most of the acetic acid was concentrated, and water and dichloromethane were added to perform extraction for two times. Then, organic phases were combined, spin-dried for removing a solvent and filtered with a silica gel funnel. A resulting compound was recrystallized with a mixture of tetrahydrofuran and methanol at a ratio of 1:4 to obtain 32.47 g of a white solid with a yield of 76.1%.

¹H NMR (400 MHz, Chloroform-d) δ 7.94 (dd, J=7.5, 1.7 Hz, 2H), 7.82 (d, J=1.3 Hz, 1H), 7.73 (d, J=7.8 Hz, 1H), 7.57-7.46 (m, 5H), 7.41-7.36 (m, 1H), 7.34-7.25 (m, 7H), 7.11 (t, J=7.5 Hz, 1H), 7.00 (d, J=8.2 Hz, 1H), 3.81 (s, 3H).

### Synthesis of a Compound 1g

The compound 1f (23.5 g, 47.72 mmol), bis(pinacolato)diboron (13.3 g, 52.5 mmol), potassium acetate (14.48 g, 143.17 mmol) and [1,1′-bis(diphenylphosphino)ferrocene]dichloropalladium (1.75 g, 2.39 mmol) were added into dioxane (240 ml) in a 500 ml one-necked flask. Stirring was performed to carry out a reaction at 90° C. for 6 hours under the protection of nitrogen. Water and dichloromethane were added to perform extraction for two times. Then, organic phases were combined and spin-dried for removing a solvent, and a residue was separated by column chromatography with a mixed solvent including ethyl acetate and n-hexane at a ratio of 1:10 to obtain 20.33 g of a white solid with a yield of 79.1%.

¹H NMR (400 MHz, Chloroform-d) δ 8.18 (s, 1H), 8.12 (d, J=7.9 Hz, 1H), 7.93 (dd, J=7.6, 1.7 Hz, 1H), 7.83 (d, J=7.3 Hz, 1H), 7.69 (d, J=1.3 Hz, 1H), 7.57-7.43 (m, 6H), 7.40-7.26 (m, 6H), 7.09 (t, J=7.1 Hz, 1H), 6.97 (d, J=8.1 Hz, 1H), 3.76 (s, 3H), 1.39 (s, 12H).

### Synthesis of a Compound 1h

The compound 1g (10 g, 18.53 mmol), a compound 1g-1 (3.7 g, 22.24 ml), potassium carbonate (7.67 g, 55.59 mmol) and tetrakis(triphenylphosphine)platinum (0.21 g, 0.185 mmol) were dissolved in a mixed solvent of 1,4-dioxane (50 ml) and water (10 ml) in a 500 ml one-necked flask. Stirring was performed to carry out a reaction at 100° C. for 12 hours under the protection of nitrogen. Then, a reaction solution was extracted with 100 ml of ethyl acetate for two times, an organic phase was spin-dried, and a residue was separated by column chromatography with a mixed solvent including ethyl acetate and n-hexane at a ratio of 1:10 to obtain 6.5 g of a white solid with a yield of 64.3%.

¹H NMR (400 MHz, Chloroform-d) δ 8.56 (d, J=3.6 Hz, 1H), 8.20 (t, J=2.0 Hz, 1H), 8.04 (d, J=2.0 Hz, 1H), 7.95 (d, J=2.2 Hz, 1H), 7.92 (dd, J=8.6, 1.3 Hz, 1H), 7.92-7.86 (m, 2H), 7.69-7.62 (m, 2H), 7.61-7.43 (m, 8H), 7.42-7.35 (m, 2H), 7.31 (dd, J=3.7, 2.2 Hz, 1H), 7.15 (ddd, J=8.6, 7.5, 1.1 Hz, 1H), 6.90 (dd, J=7.7, 1.2 Hz, 1H), 3.90 (s, 3H), 1.37 (s, 9H).

### Synthesis of a Compound 1i

The compound 1h (5.8 g, 10.63 mmol), pyridine hydrochloride (58 g, 0.5 mol) and o-dichlorobenzene (10 ml) were put into a 250 ml one-necked flask. Stirring was performed to carry out a reaction at 100° C. for 10 hours under the protection of nitrogen. Then, a reaction solution was extracted with 100 ml of ethyl acetate for two times, an organic phase was spin-dried, and a residue was separated by column chromatography with a mixed solvent including ethyl acetate and n-hexane at a ratio of 1:5 to obtain 5.5 g of a yellow powder product with a yield of 97.5%.

¹H NMR (400 MHz, Chloroform-d) δ 8.56 (d, J=3.6 Hz, 1H), 8.20 (t, J=2.0 Hz, 1H), 8.04 (d, J=2.2 Hz, 1H), 8.00 (dd, J=8.7, 1.2 Hz, 1H), 7.92-7.85 (m, 3H), 7.69-7.62 (m, 2H), 7.61-7.43 (m, 8H), 7.41-7.34 (m, 1H), 7.31 (dd, J=3.7, 2.2 Hz, 1H), 7.25 (td, J=8.0, 1.3 Hz, 1H), 7.02-6.94 (m, 2H), 1.37 (s, 9H).

### Synthesis of a Complex 1

The compound 1i (5 g, 9.4 mmol), K₂PtCl₄ (5.64 g, 14.1 mmol) and tetrabutylammonium bromide (TBAB, 438.6 mg, 1.41 mmol) were dissolved in acetic acid (400 mL) in a 1 L one-necked flask. Stirring was performed to carry out a reaction at 135° C. for 72 hours under the protection of nitrogen. Water was added into a reaction solution to precipitate a solid, and the reaction solution was filtered to obtain a crude product. Then, a reside was treated with dichloromethane, filtered with a silica gel funnel, spin-dried, mixed with silica gel and separated by column chromatography with a mixed solvent including ethyl acetate and n-hexane at a ratio of 5:1 to obtain 5.12 g of an orange-yellow powder product with a yield of 72.7%.

¹H NMR (500 MHz, Chloroform-d) δ 8.91 (d, J=8.9 Hz, 1H), 7.94 (dd, J=8.2, 1.2 Hz, 1H), 7.80 (d, J=2.2 Hz, 1H), 7.74-7.69 (m, 2H), 7.61-7.43 (m, 13H), 7.41-7.34 (m, 1H), 7.30 (td, J=7.4, 1.2 Hz, 1H), 7.17 (dd, J=7.5, 1.2 Hz, 1H), 7.09 (ddd, J=8.4, 7.5, 1.3 Hz, 1H), 7.00 (s, 1H), 1.37 (s, 7H). ESI-MS (m/z): 723.2 (M+1).

### Example 2: Synthesis of a Complex 8

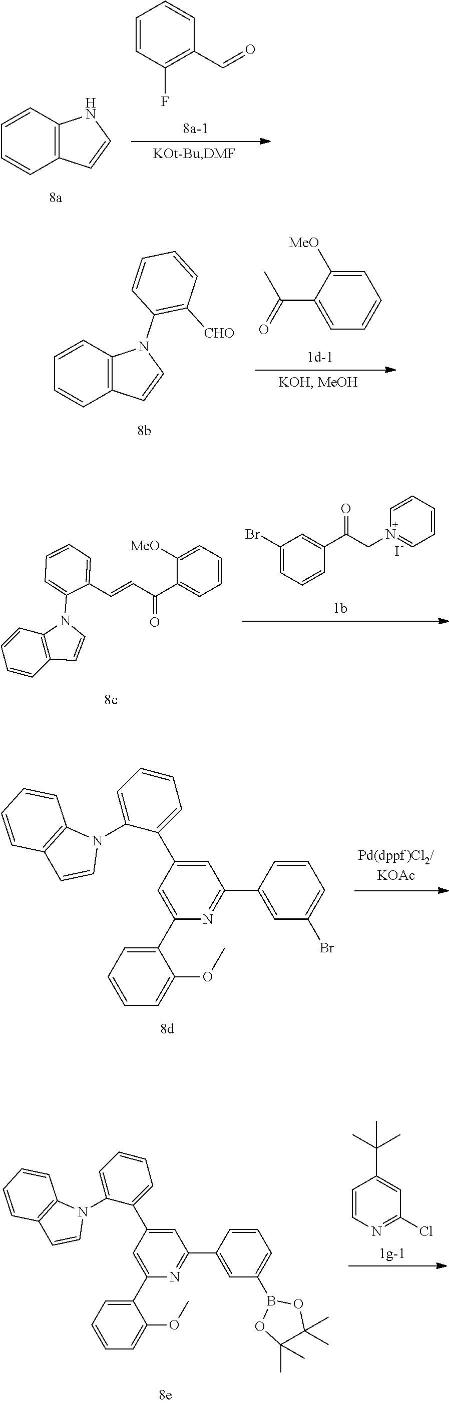

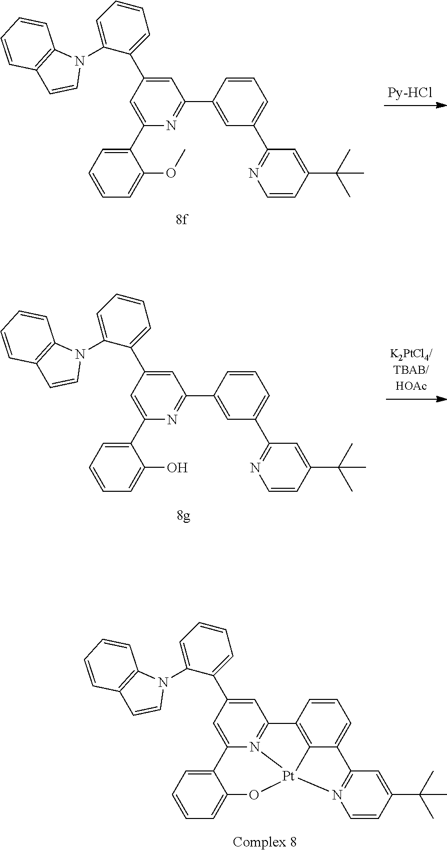

### Synthesis of a Compound 8b

A compound 8a (20 g, 117.15 mmol), a compound 8a-1 (29.08 g, 234.3 mmol), K₂CO₃ (48.5 g, 351.45 mmol) and N,N-dimethylformamide (DMF, 1 L) were put into a 2 L three-necked flask and stirred to carry out a reaction at 150° C. for 72 hours under the protection of nitrogen. After the reaction was completed, most of the DMF was concentrated, and water and dichloromethane were added to perform extraction for two times. Then, organic phases were combined and spin-dried for removing a solvent to obtain a brownish black oily liquid, and the oily liquid was separated by column chromatography with a mixed solvent including ethyl acetate and n-hexane at a ratio of 1:15 to obtain 18.01 g of a colorless oily compound 8b with a reaction yield of 69.5% in total.

¹H NMR (400 MHz, Chloroform-d) δ 9.48 (d, J=0.7 Hz, 1H), 7.89 (dd, J=7.0, 1.2 Hz, 1H), 7.79 (dt, J=6.8, 1.4 Hz, 1H), 7.67-7.60 (m, 2H), 7.59-7.53 (m, 2H), 7.37 (td, J=7.0, 1.3 Hz, 1H), 7.30 (td, J=6.6, 1.2 Hz, 1H), 7.21-7.14 (m, 1H), 6.86 (dd, J=5.1, 1.2 Hz, 1H).

### Synthesis of a Compound 8c

The compound 8b (17 g, 76.8 mmol), a compound 1d-1 (11.5 g, 76.8 mmol) and MeOH (250 ml) were put into a 500 ml one-necked flask, a KOH aqueous solution (3.36 g dissolved in 30 ml of water) was added dropwise under stirring at room temperature, and after the dropping was completed, a resulting mixture was stirred at room temperature overnight for 12 hours. After a reaction was completed, a large amount of a solid was precipitated. Then, the solid was directly subjected to suction filtration, washed with a small amount of methanol for several times and dried to obtain 22.28 g of a white solid compound 8c with a reaction yield of 82.1%.

¹H NMR (400 MHz, Chloroform-d) δ 8.07-8.00 (m, 1H), 7.92 (dd, J=7.4, 1.8 Hz, 1H), 7.79 (dt, J=6.6, 1.4 Hz, 1H), 7.67-7.59 (m, 2H), 7.54 (dd, J=5.0, 1.5 Hz, 2H), 7.55-7.47 (m, 2H), 7.47 (ddd, J=8.4, 7.4, 1.7 Hz, 1H), 7.33-7.25 (m, 2H), 7.16 (dtd, J=17.2, 7.1, 1.4 Hz, 2H), 7.07 (dd, J=8.4, 1.3 Hz, 1H), 6.88-6.83 (m, 1H), 3.88 (s, 3H).

### Synthesis of a Compound 8d

The compound 8c (15 g, 42.4 mmol), the compound 1b (17.14 g, 42.4 mmol), ammonium acetate (70.0 g) and acetic acid (200 ml) were put into a 500 ml one-necked flask to carry out a reaction at 130° C. for 8 hours. After the reaction was completed, a reaction solution was slowly added into an ice water bath for cooling until a large amount of a greyish green solid was precipitated. Then, the greyish green solid was subjected to suction filtration and dried to obtain a greyish green crude product, and the crude product was separated by column chromatography with a mixed solvent including ethyl acetate and n-hexane at a ratio of 1:15 to obtain 12.1 g of a yellow foam-like solid with a reaction yield of 53.7%.

¹H NMR (400 MHz, Chloroform-d) δ 8.22 (t, J=1.9 Hz, 1H), 8.03-7.97 (m, 2H), 7.96-7.90 (m, 2H), 7.80 (dt, J=7.0, 1.2 Hz, 1H), 7.67 (dd, J=6.9, 1.2 Hz, 1H), 7.63 (ddd, J=12.5, 6.3, 1.4 Hz, 2H), 7.58-7.51 (m, 2H), 7.46-7.38 (m, 2H), 7.38 (dd, J=7.6, 1.2 Hz, 1H), 7.29 (dtd, J=8.4, 6.8, 1.2 Hz, 2H), 7.21-7.11 (m, 2H), 6.90 (dd, J=7.7, 1.2 Hz, 1H), 6.88-6.83 (m, 1H), 3.90 (s, 3H).

### Synthesis of a Compound 8e

The compound 8d (7.6 g, 14.3 mmol), bis(pinacolato)diboron (5.44 g, 21.4 mmol), palladium acetate (160.5 mg, 0.72 mmol), X-phos (667.4 mg, 1.4 mmol), potassium acetate (4.2 g, 42.9 mmol) and dioxane (250 ml) were put into a 500 ml one-necked flask and stirred to carry out a reaction at 90° C. for 9 hours under the protection of nitrogen. After the reaction was completed, suction filtration was directly performed. Then, a mother liquid was directly spin-dried and separated by column chromatography with a mixed solvent including ethyl acetate and n-hexane at a ratio of 1:15. 6.4 g of a white solid compound 8e with a reaction yield of 77.36% was collected in total.

¹H NMR (400 MHz, Chloroform-d) δ 8.06 (t, J=1.9 Hz, 1H), 7.99 (d, J=2.2 Hz, 1H), 7.95-7.90 (m, 2H), 7.82-7.76 (m, 2H), 7.74 (ddd, J=7.1, 1.9, 1.2 Hz, 1H), 7.67 (dd, J=6.9, 1.2 Hz, 1H), 7.63 (ddd, J=12.5, 6.3, 1.4 Hz, 2H), 7.55-7.47 (m, 2H), 7.45-7.35 (m, 2H), 7.32-7.25 (m, 2H), 7.21-7.12 (m, 2H), 6.90 (dd, J=7.7, 1.2 Hz, 1H), 6.87-6.83 (m, 1H), 3.90 (s, 3H), 1.24 (s, 12H).

### Synthesis of a Compound 8f

The compound 8e (6 g, 10.37 mmol), a compound 1g-1 (2.1 g, 12.4 mmol), Pd₁₃₂ (367 mg, 0.52 mmol), K₂CO₃ (4.29 g, 31.1 mmol), dioxane (160 ml) and water (40 ml) were put into a 500 ml one-necked flask and stirred to carry out a reaction at 90° C. for 16 hours under the protection of nitrogen. After the reaction was completed, the dioxane was removed by spin-drying. Then, a reaction solution was extracted with 100 ml of ethyl acetate for two times, an organic phase was spin-dried, and a residue was separated by column chromatography with a mixed solvent including ethyl acetate and n-hexane at a ratio of 1:6. 4.1 g of a light yellow solid compound 8f with a reaction yield of 67.2% was collected in total.

¹H NMR (400 MHz, Chloroform-d) δ 8.56 (d, J=3.6 Hz, 1H), 8.20 (t, J=2.0 Hz, 1H), 8.02 (d, J=2.0 Hz, 1H), 7.96-7.86 (m, 4H), 7.80 (dt, J=6.9, 1.2 Hz, 1H), 7.70-7.63 (m, 3H), 7.63 (ddd, J=12.4, 5.6, 1.6 Hz, 2H), 7.53 (d, J=5.1 Hz, 1H), 7.46-7.35 (m, 2H), 7.34-7.28 (m, 2H), 7.30-7.25 (m, 1H), 7.21-7.11 (m, 2H), 6.90 (dd, J=7.7, 1.2 Hz, 1H), 6.88-6.83 (m, 1H), 3.90 (s, 3H), 1.37 (s, 9H).

### Synthesis of a Compound 8g

The compound 8f (4 g, 6.82 mmol), pyridine hydrochloride (40 g) and 2.4 mL of o-dichlorobenzene were put into a 250 ml one-necked flask to carry out a reaction at 180° C. for 12 hours under the protection of nitrogen. After the reaction was completed, a reaction solution was extracted and washed with a dichloromethane and water system for two times, and an organic phase was spin-dried. Then, a residue was separated by column chromatography with a mixed solvent including ethyl acetate and n-hexane at a ratio of 1:6 to obtain 3.1 g of a light yellow solid compound 8g with a reaction yield of 79.5%.

¹H NMR (400 MHz, Chloroform-d) δ 8.56 (d, J=3.6 Hz, 1H), 8.20 (t, J=2.0 Hz, 1H), 8.05-7.98 (m, 2H), 7.92-7.86 (m, 3H), 7.80 (dt, J=7.1, 1.3 Hz, 1H), 7.70-7.59 (m, 5H), 7.53 (d, J=5.1 Hz, 1H), 7.46-7.39 (m, 1H), 7.34-7.28 (m, 2H), 7.30-7.25 (m, 1H), 7.25 (td, J=8.0, 1.3 Hz, 1H), 7.17 (td, J=6.8, 1.6 Hz, 1H), 7.02-6.94 (m, 2H), 6.88-6.83 (m, 1H), 1.37 (s, 9H).

### Synthesis of a Complex 8

The compound 8g (2.5 g, 4.37 mmol), K₂PtCl₄ (2.47 g, 6.56 mmol) and tetrabutylammonium bromide (TBAB, 211.3 mg, 0.65 mmol) were dissolved in acetic acid (250 mL) in a 500 ml one-necked flask. Stirring was performed to carry out a reaction at 135° C. for 72 hours under the protection of nitrogen. Water was added into a reaction solution to precipitate a solid, and the reaction solution was filtered to obtain a crude product. Then, a reside was treated with dichloromethane, filtered with a silica gel funnel, spin-dried, mixed with silica gel and separated by column chromatography with a mixed solvent including ethyl acetate and n-hexane at a ratio of 1:5 to obtain a product. 2.34 g of an orange-yellow powder complex 8 with a yield of 70.1% was obtained in total.

¹H NMR (400 MHz, Chloroform-d) δ 8.91 (d, J=8.9 Hz, 1H), 8.08-8.03 (m, 2H), 7.94 (dd, J=8.2, 1.2 Hz, 1H), 7.80 (td, J=3.7, 3.1, 1.5 Hz, 2H), 7.67-7.47 (m, 7H), 7.43 (ddd, J=7.3, 6.3, 1.2 Hz, 1H), 7.29 (tdd, J=7.0, 6.2, 1.2 Hz, 3H), 7.18 (ddd, J=7.5, 4.8, 1.4 Hz, 2H), 7.09 (ddd, J=8.4, 7.5, 1.3 Hz, 1H), 7.00 (s, 1H), 6.88-6.83 (m, 1H), 1.37 (s, 9H). ESI-MS (m/z): 764.2 (M+1).

### Example 3: Synthesis of a Complex 16

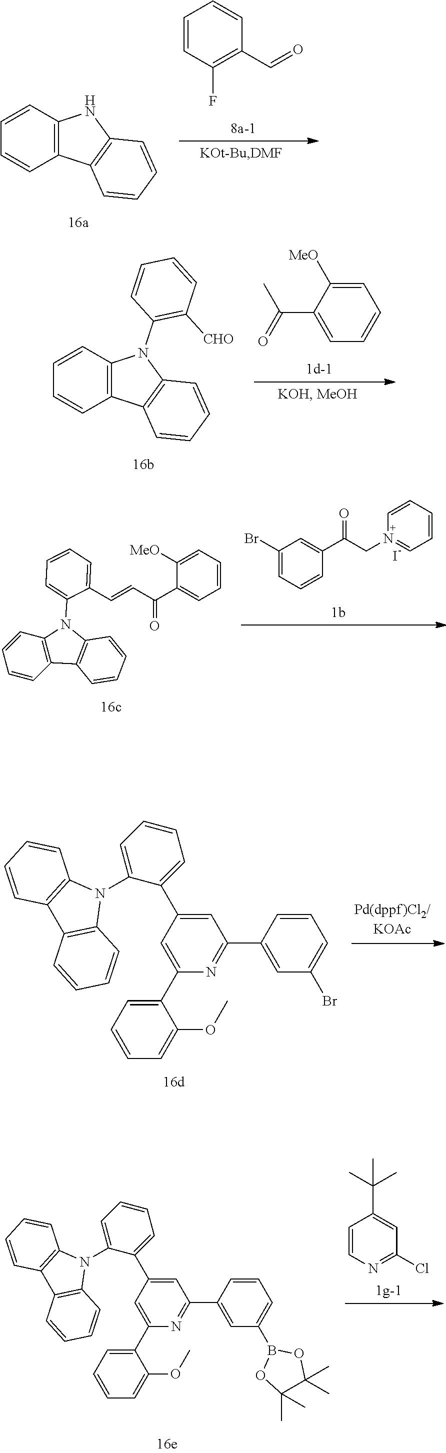

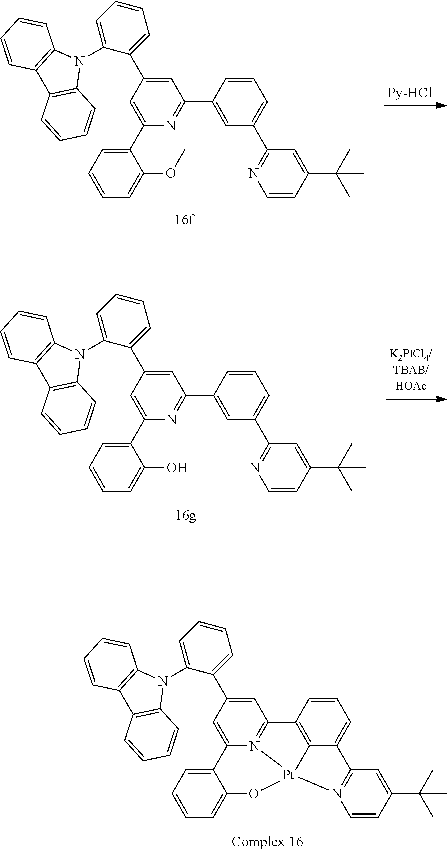

### Synthesis of a Compound 16b

A compound 8a (6.68 g, 40.0 mmol), 8b (10.0 g, 80.0 mmol), K₂CO₃ (8.28 g, 60.0 mmol) and DMF (400 ml) were put into a 1 L three-necked flask and stirred to carry out a reaction at 150° C. for 72 hours under the protection of nitrogen. After the reaction was completed, a reaction solution was extracted and washed with dichloromethane and water for two times, and an organic phase was spin-dried to obtain a brownish black oily liquid. Then, a sample was separated by column chromatography with a mixed solvent including ethyl acetate and n-hexane at a ratio of 1:15 to obtain 17.0 g of a light yellow oily compound 16b with a reaction yield of 78.4%.

1H NMR (400 MHz, CDCl₃) δ 9.60 (d, J=0.7 Hz, 1H), 8.22 (dd, J=7.8, 1.4 Hz, 1H), 8.18 (d, J=7.5 Hz, 2H), 7.85 (td, J=7.7, 1.6 Hz, 1H), 7.67 (t, J=7.6 Hz, 1H), 7.55 (dd, J=7.9, 0.7 Hz, 1H), 7.46-7.38 (m, 2H), 7.37-7.29 (m, 2H), 7.17 (d, J=8.1 Hz, 2H).

### Synthesis of a Compound 16c

The compound 16b (5.42 g, 20.0 mmol), a compound 1d-1 (3.0 g, 20.0 mmol) and MeOH (80 ml) were put into a 250 ml one-necked flask, a KOH aqueous solution (1.12 g dissolved in 10 ml of water) was added dropwise under stirring at room temperature, and after the dropping was completed, a resulting mixture was stirred at room temperature overnight for 16 hours. After a reaction was completed, a large amount of a solid was precipitated. Then, the solid was directly subjected to suction filtration, washed with a small amount of methanol for several times and dried to obtain 6.8 g of a white solid compound 16c with a reaction yield of 84.4% in total.

1H NMR (400 MHz, CDCl₃) δ 8.12 (d, J=7.7 Hz, 2H), 8.00-7.94 (m, 1H), 7.59 (p, J=7.5 Hz, 2H), 7.47-7.41 (m, 1H), 7.35 (t, J=7.6 Hz, 2H), 7.28 (d, J=7.1 Hz, 2H), 7.23 (s, 1H), 7.13 (d, J=16.1 Hz, 1H), 7.07-6.97 (m, 4H), 6.69 (dd, J=15.9, 8.0 Hz, 2H), 3.57 (s, 3H).

### Synthesis of a Compound 16d

The compound 16c (12.9 g, 32.0 mmol), 1b (12.9 g, 32.0 mmol), ammonium acetate (62.0 g) and acetic acid (130 ml) were put into a 250 ml one-necked flask to carry out a reaction at 130° C. for 8 hours. After the reaction was completed, a reaction solution was slowly added into an ice water bath for cooling until a large amount of a greyish green solid sample was precipitated. Then, the greyish green solid sample was subjected to suction filtration and dried to obtain a greyish green crude product, and the crude product was separated by column chromatography with a mixed solvent including ethyl acetate and n-hexane at a ratio of 1:15 to obtain 10.5 g of a yellow foam-like solid compound 16d with a reaction yield of 56.5%.

1H NMR (400 MHz, CDCl₃) δ 8.08 (d, J=7.7 Hz, 2H), 7.77 (t, J=3.8 Hz, 2H), 7.75-7.71 (m, 1H), 7.68 (dt, J=7.2, 3.6 Hz, 2H), 7.66-7.61 (m, 1H), 7.53 (d, J=1.6 Hz, 1H), 7.40-7.35 (m, 2H), 7.35-7.31 (m, 2H), 7.24 (s, 1H), 7.18-7.11 (m, 3H), 7.09 (s, 1H), 7.06 (dd, J=8.0, 1.4 Hz, 2H), 6.99-6.91 (m, 2H), 3.74 (s, 3H).

### Synthesis of a Compound 16e

The compound 16d (3.5 g, 6.0 mmol), bis(pinacolato)diboron (2.29 g, 9.0 mmol), palladium acetate (67 mg, 0.3 mmol), X-phos (283 mg, 0.6 mmol), potassium acetate (1.77 g, 18.0 mmol) and dioxane (100 ml) were put into a 250 ml one-necked flask and stirred to carry out a reaction at 90° C. for 12 hours under the protection of nitrogen. After the reaction was completed, suction filtration was directly performed. Then, a mother liquid was directly spin-dried and separated by column chromatography with a mixed solvent including ethyl acetate and n-hexane at a ratio of 1:15 to obtain 3.5 g of a white compound product 16e with a reaction yield of 92.5%.

¹H NMR (400 MHz, CDCl₃) δ 8.18 (s, 1H), 8.03 (d, J=7.7 Hz, 2H), 7.76 (dd, J=12.5, 5.8 Hz, 2H), 7.65 (dt, J=11.3, 7.6 Hz, 3H), 7.60-7.52 (m, 2H), 7.46 (d, J=7.9 Hz, 1H), 7.34-7.26 (m, 5H), 7.17 (dd, J=18.0, 7.8 Hz, 4H), 6.98 (t, J=7.4 Hz, 1H), 6.86 (d, J=8.2 Hz, 1H), 3.56 (s, 3H), 1.36 (s, 12H).

### Synthesis of a Compound 16f

The compound 16e (5.9 g, 11.8 mmol, 1.0 eq), a compound 1g-1 (2.4 g, 14.1 mmol), tris(dibenzylideneacetone)dipalladium (538 mg, 0.59 mmol, 0.05 eq), X-phos (563 mg, 1.18 mmol), K₂CO₃ (4.88 g, 35.3 mmol), dioxane (160 ml) and water (40 ml) were put into a 500 ml one-necked flask and stirred to carry out a reaction at 90° C. for 16 hours under the protection of nitrogen. After the reaction was completed, the dioxane was removed by spin-drying. Then, a reaction solution was extracted and washed with an ethyl acetate (EA)/water system, an organic phase was spin-dried, and a residue was separated by column chromatography with a mixed solvent including ethyl acetate and n-hexane at a ratio of 1:6 to obtain 3.6 g of a light yellow solid compound 16f with a yield of 60.3%.

1H NMR (400 MHz, CDCl₃) δ 8.61 (d, J=5.2 Hz, 1H), 8.38 (s, 1H), 8.01 (d, J=7.7 Hz, 2H), 7.88 (d, J=7.3 Hz, 1H), 7.81-7.76 (m, 1H), 7.68 (dd, J=6.3, 4.4 Hz, 3H), 7.65 (d, J=6.9 Hz, 1H), 7.64-7.56 (m, 2H), 7.40-7.26 (m, 5H). 7.25-7.19 (m, 2H), 7.16 (t, J=7.0 Hz, 4H), 6.98 (t, J=7.5 Hz, 1H), 6.89 (d, J=8.3 Hz, 1H), 3.60 (s, 3H), 1.37 (s, 9H).

### Synthesis of a Compound 16g

The compound 16f (2.4 g, 3.77 mmol), pyridine hydrochloride (24 g) and 2.4 mL of o-dichlorobenzene were put into a 50 ml one-necked flask to carry out a reaction at 175° C. for 12 hours under the protection of nitrogen. After the reaction was completed, a reaction solution was extracted and washed with a dichloromethane/water system for two times, an organic phase was spin-dried, and a residue was separated by column chromatography with a mixed solvent including ethyl acetate and n-hexane at a ratio of 1:6 to obtain 2.0 g of a light yellow solid compound 16g with a reaction yield of 85.21% in total.

1H NMR (400 MHz, CDCl₃) δ 8.64 (d, J=5.2 Hz, 1H), 8.33 (s, 1H), 8.04 (d, J=7.7 Hz, 2H), 7.97 (d, J=7.6 Hz, 1H), 7.86-7.81 (m, 1H), 7.77-7.70 (m, 3H), 7.69-7.64 (m, 1H), 7.49-7.43 (m, 2H), 7.42-7.31 (m, 4H), 7.29 (dd, J=5.2, 1.7 Hz, 1H), 7.24-7.16 (m, 3H), 7.13 (d, J=8.1 Hz, 2H), 6.89 (d, J=8.3 Hz, 1H), 6.64 (d, J=6.1 Hz, 2H), 1.40 (s, 9H).

### Synthesis of a Complex 16

The compound 16g (1.5 g, 2.41 mmol), K₂PtCl₄ (1.2 g, 2.90 mmol), tetrabutylammonium bromide (TBAB, 117 mg, 0.36 mmol) and acetic acid (150 mL) were put into a 250 ml one-necked flask to carry out a reaction at 130° C. for 48 hours under the protection of nitrogen. After the reaction was completed, an excess amount of deionized water was added to precipitate a solid. Then, suction filtration was performed, the solid was dissolved in dichloromethane, an organic phase was spin-dried and separated by column chromatography with dichloromethane as an eluting agent, and a resulting crude sample was separated and purified for one time by column chromatography with a mixed solvent including n-hexane, dichloromethane and ethyl acetate at a ratio of 10:10:1 to obtain 1.5 g of an orange solid complex 16 in total. Finally, the solid was recrystallized with a mixture of dichloromethane and n-hexane at a ratio of 1:2 to obtain 1.27 g of an orange solid with a reaction yield of 64.6%.

1H NMR (400 MHz, CDCl₃) δ 8.69 (d, J=6.0 Hz, 1H), 8.06 (d, J=7.8 Hz 2H), 7.88-7.83 (m, 1H), 7.78-7.73 (m, 2H), 7.68 (dd, J=8.7, 4.4 Hz, 2H), 7.59 (s, 1H), 7.37 (t, J=7.3 Hz, 2H), 7.28 (s, 2H), 7.21 (dd, J=16.6, 6.1 Hz, 6H), 7.16 (s, 1H), 6.83 (t, J=7.6 Hz, 1H), 6.78-6.69 (m, 2H), 6.35 (t, J=7.4 Hz, 1H), 1.39 (s, 9H).

Persons skilled in the art shall know that the above preparation method is only an exemplary example. For persons skilled in the art, other compound structures of the present invention can be obtained through modification of the above method.

### Example 4

Under the atmosphere of nitrogen, samples of fully dried platinum complex 1, 9 and 16 with a weight of about 5.0 mg were separately weighed. At a heat scanning speed of 10° C./min in a scanning range of 25-800° C., these samples were determined to have a thermal decomposition temperature of 416° C., 403° C. and 427° C., respectively (temperature corresponding to a thermal weight loss of 0.5%), showing that these complexes have excellent thermal stability.

### Example 5

An organic light-emitting diode was prepared by using a complex luminescent material of the present invention. The structure of the device is as shown in FIG. 1.

First, a transparent conductive indium tin oxide (ITO) glass substrate 10 (with an anode 20) was sequentially washed with a detergent solution, deionized water, ethanol, acetone and deionized water, and then treated with oxygen plasma for 30 seconds.

Then, HATCN with a thickness of 10 nm was evaporated on the ITO to serve as a hole injection layer 30.

Then, a compound HT was evaporated to form a hole transport layer 40 with a thickness of 40 nm.

Then, a light-emitting layer 50 with a thickness of 20 nm was evaporated on the hole transport layer, where the light-emitting layer was formed by mixed doping of a platinum complex 1 (20%) and CBP (80%).

Then, AlQ₃ with a thickness of 40 nm was evaporated on the light-emitting layer to serve as an electron transport layer 60.

Finally, LiF with a thickness of 1 nm and Al with a thickness of 100 nm were evaporated to serve as an electron injection layer 70 and a device cathode 80, respectively.

Example 6: An organic light-emitting diode was prepared by the method as described in Example 5 when a complex 1 was replaced with a complex 8.

Example 7: An organic light-emitting diode was prepared by the method as described in Example 5 when a complex 1 was replaced with a complex 16.

### Comparative Example 1

An organic light-emitting diode was prepared by the method as described in Example 7 when a complex 1 was replaced with a complex Ref-1 (CN110872325A).

### Comparative Example 2

An organic light-emitting diode was prepared by the method as described in Example 7 when a complex 1 was replaced with a complex Ref-2 (Chem. Sci., 2014, 5, 4819).

Structural formulas of the HATCN, the HT, the AlQ₃, the Ref-1, the Ref-2 and the CBP in a device are shown as follows:

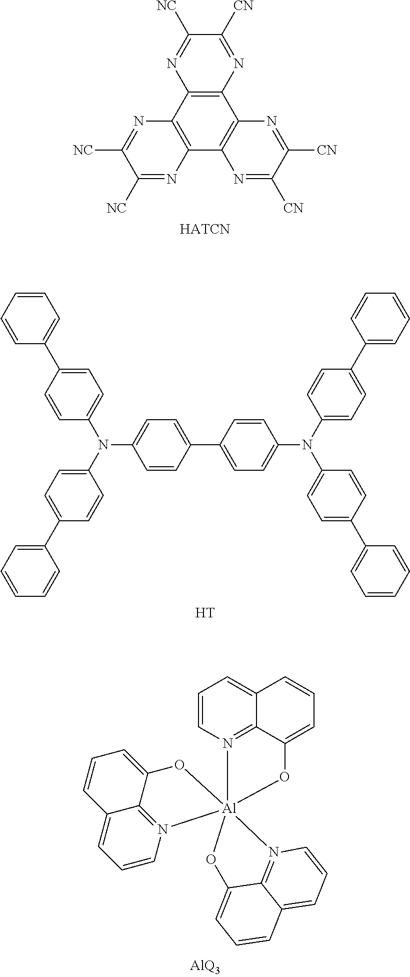

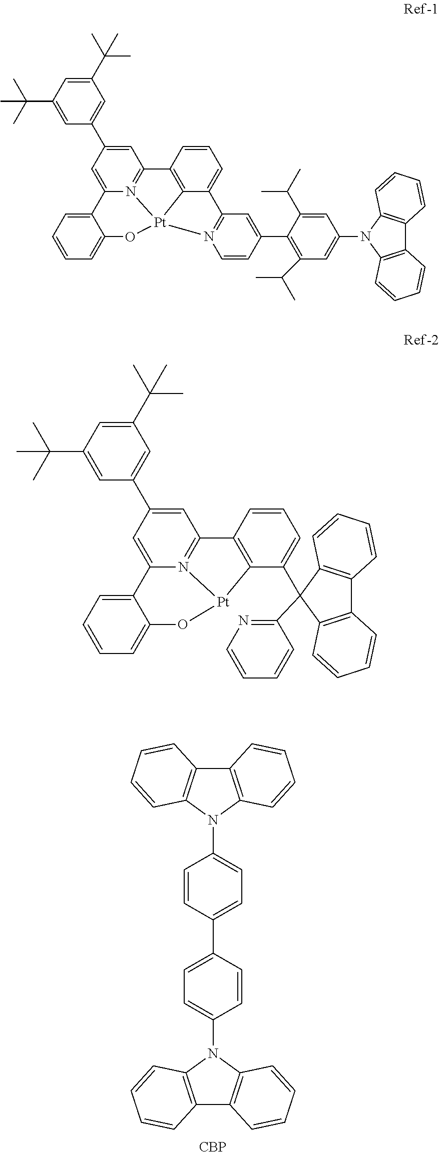

Device properties of organic electroluminescent devices in Example 5, Example 6, Example 7, Comparative Example 1 and Comparative Example 2 at a current density of 20 mA/cm² are listed in Table 1:

TABLE 1

| Device | | Driving | Luminous | Device life |
|---|---|---|---|---|
| number | Complex | voltage | efficiency | (LT95) |
| Example 5 | Complex 1 | 1 | 1 | 1 |
| Example 6 | Complex 8 | 0.9 | 1.1 | 0.81 |
| Example 7 | Complex 16 | 1 | 1.4 | 1.3 |
| Comparative | Ref-1 | 1.1 | 0.95 | 0.51 |
| Example 1 | | | | |
| Comparative | Ref-2 | 1.1 | 0.91 | 0.30 |
| Example 2 | | | | |

Note:
The device properties were tested based on Example 5, and each index was set to 1; and LT95 refers to corresponding time when the brightness of a device is reduced to 95% of the initial brightness (10,000 d/m²).

It can be seen from the data in Table 1 that under the same conditions, the platinum complex material of the present invention has a lower driving voltage and higher luminous efficiency when applied to an organic light-emitting diode. In addition, an organic light-emitting diode based on the complex of the present invention has obviously better device life than complex materials in comparative examples, which can meet requirements of the display industry for luminescent materials and has a good industrialization prospect.

The various embodiments are merely used as examples and are not intended to limit the scope of the present invention. Without parting from the spirit of the present invention, various materials and structures in the present invention can be replaced by other materials and structures. It is to be understood that many modifications and changes can be made by persons skilled in the art without creative labor according to the ideas of the present invention. Therefore, technical schemes that can be obtained by technical persons through analysis, reasoning or partial research on the basis of existing technologies fall within the scope of protection limited by the claims.

1. A heterocyclic modified platinum complex containing an ONCN tetradentate ligand, having a structure as shown in Formula (I): 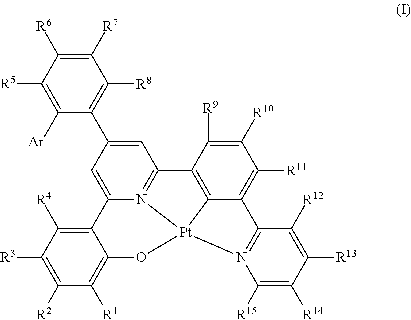
wherein
R¹ to R¹⁵ are independently selected from hydrogen, deuterium, halogen, amino, carbonyl, carboxyl, alkylthio, cyano, sulfonyl, phosphino, substituted or unsubstituted alkyl containing 1-20 carbon atoms, substituted or unsubstituted cycloalkyl containing 3-20 cyclic carbon atoms, substituted or unsubstituted alkenyl containing 2-20 carbon atoms, and substituted or unsubstituted alkoxyl containing 1-20 carbon atoms;
Ar is selected from substituted or unsubstituted aryl containing 6-30 carbon atoms, and substituted or unsubstituted heteroaryl containing 3-30 carbon atoms;
the heteroaryl comprises one or more of N, S and O heteroatoms;
and the “substituted” refers to substitution with halogen, amino, cyano, C₁-C₄ alkyl, or fluorinated C₁-C₄ alkyl.

2. The platinum complex according to claim 1, wherein the R¹ to R¹⁵ are independently selected from hydrogen, deuterium, halogen, amino, alkylthio, cyano, substituted or unsubstituted alkyl containing 1-6 carbon atoms, substituted or unsubstituted cycloalkyl containing 3-6 cyclic carbon atoms, substituted or unsubstituted alkenyl containing 2-6 carbon atoms, and substituted or unsubstituted alkoxyl containing 1-6 carbon atoms;
the Ar is selected from substituted or unsubstituted aryl containing 6-30 carbon atoms, and substituted or unsubstituted heteroaryl containing 3-30 carbon atoms;
and the “substituted” refers to substitution with halogen, amino, cyano, C₁-C₄ alkyl, or fluorinated C₁-C₄ alkyl.

3. The platinum complex according to claim 1, wherein the R¹ to R¹⁵ are independently selected from hydrogen, deuterium, halogen, cyano, C₁-C₄ alkyl, and substituted or unsubstituted cycloalkyl containing 3-6 cyclic carbon atoms;
the Ar is selected from substituted or unsubstituted aryl containing 6-30 carbon atoms, and substituted or unsubstituted heteroaryl containing 3-30 carbon atoms;
and the “substituted” refers to substitution with halogen, amino, cyano, C₁-C₄ alkyl, or fluorinated C₁-C₄ alkyl.

4. The platinum complex according to claim 1, wherein the R¹ to R¹⁵ are independently selected from hydrogen, deuterium, cyano, methyl, isopropyl, isobutyl, tert-butyl, substituted or unsubstituted cyclopentyl, and substituted or unsubstituted cyclohexyl;
the Ar is selected from substituted or unsubstituted phenyl, substituted or unsubstituted pyridinyl, substituted or unsubstituted pyrazinyl, substituted or unsubstituted pyrimidinyl, substituted or unsubstituted imidazolyl, and substituted or unsubstituted carbazolyl;
and the “substituted” refers to substitution with halogen, cyano, C₁-C₄ alkyl, or fluorinated C₁-C₄ alkyl.

5. The platinum complex according to claim 1, wherein in General Formula (I), the R¹ to R¹⁵ are independently selected from hydrogen, deuterium, methyl, tert-butyl, and cyano;
the Ar is selected from substituted or unsubstituted phenyl, substituted or unsubstituted pyridinyl, substituted or unsubstituted imidazolyl, and substituted or unsubstituted carbazolyl;
and the “substituted” refers to substitution with halogen, amino, cyano, C₁-C₄ alkyl, or fluorinated C₁-C₄ alkyl.

6. The platinum complex according to claim 1, wherein in General Formula (I), the R¹³ in the R¹ to R¹⁵ is tert-butyl, and other groups are hydrogen;
and the Ar is selected from substituted or unsubstituted phenyl, substituted or unsubstituted pyridinyl, or substituted or unsubstituted carbazolyl.

7. The metallic platinum complex according to claim 1, being one of the following compounds:

| | |
|---|---|
| 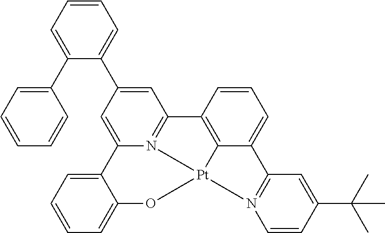 | 1 |
| 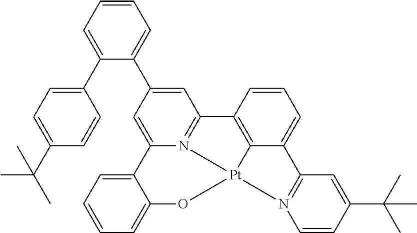 | 2 |
| 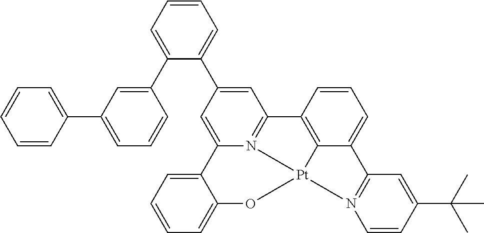 | 3 |
| 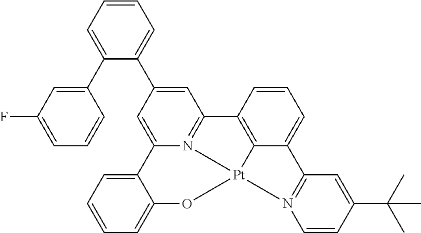 | 4 |
| 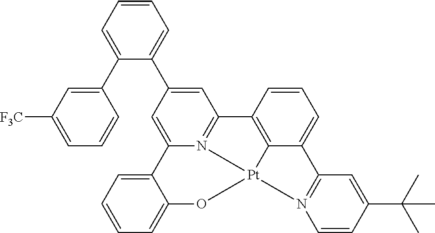 | 5 |
| 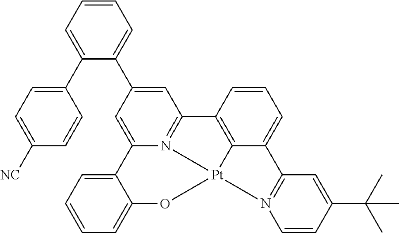 | 6 |
| 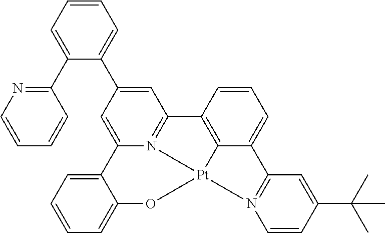 | 7 |
| 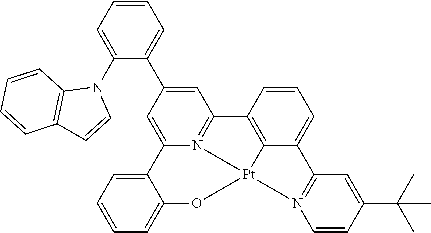 | 8 |
| 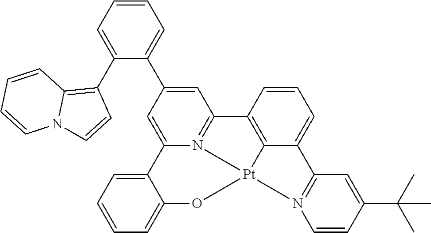 | 9 |
| 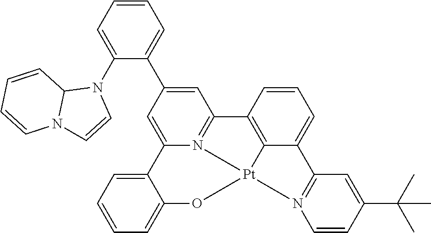 | 10 |
| 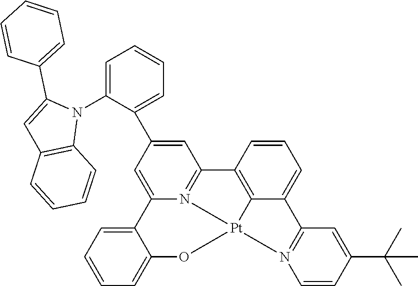 | 11 |
| 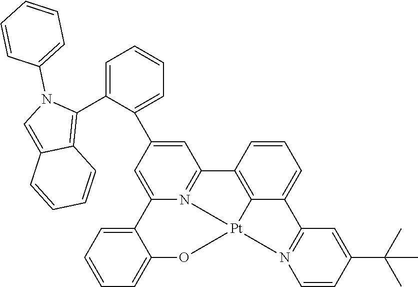 | 12 |
| 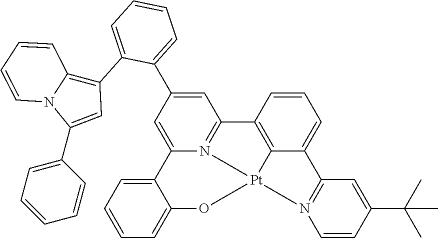 | 13 |
| 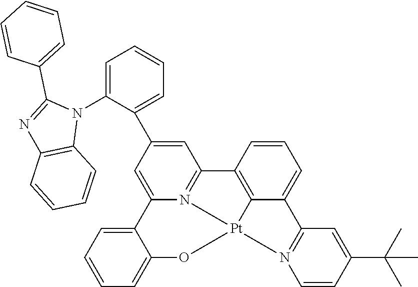 | 14 |
| 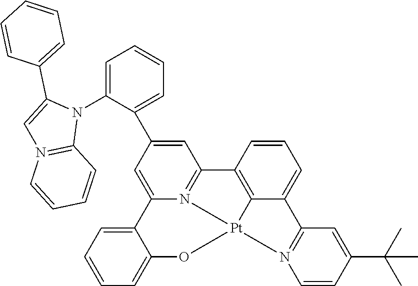 | 15 |
| 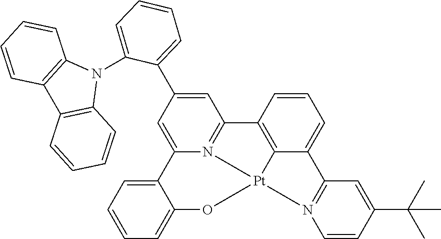 | 16 |
| 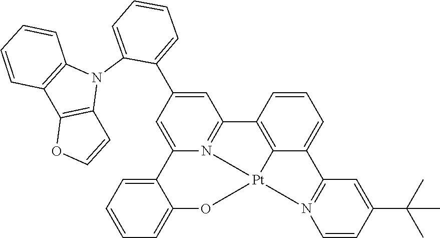 | 17 |
| 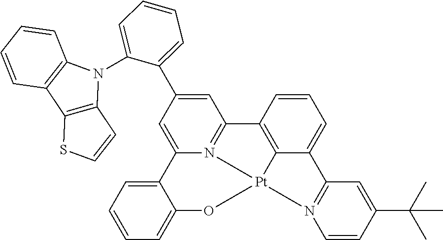 | 18 |
| 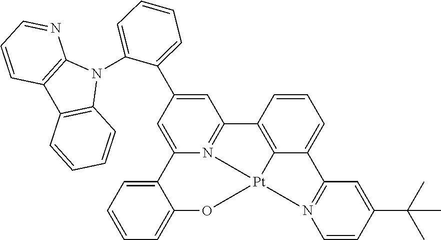 | 19 |
| 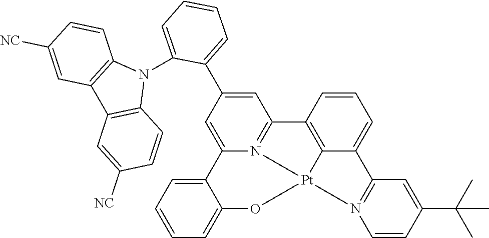 | 20 |
| 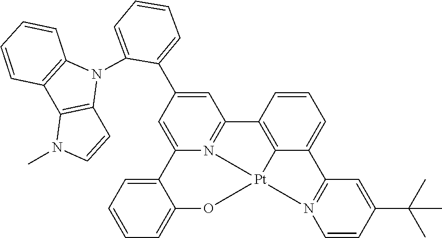 | 21 |
| 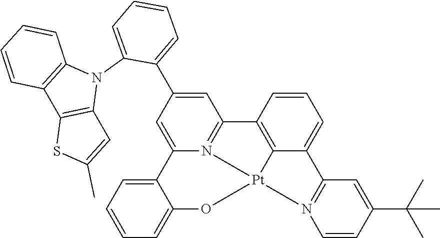 | 22 |
| 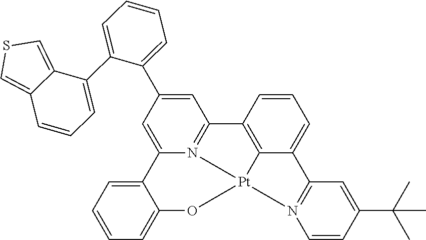 | 23 |
| 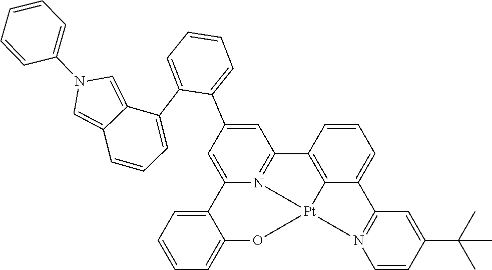 | 24 |
| 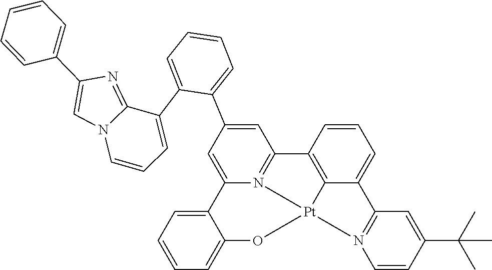 | 25 |
| 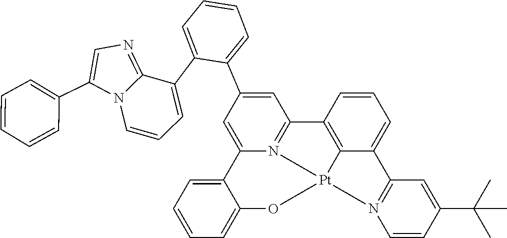 | 26 |
| 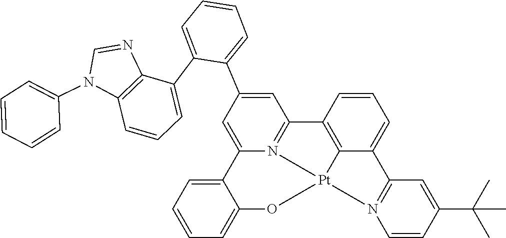 | 27 |
| 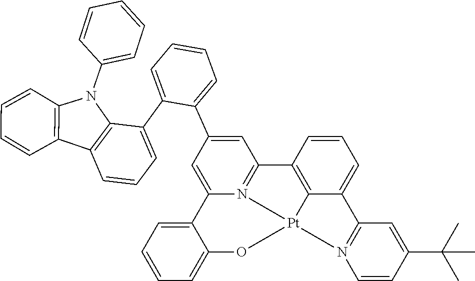 | 28 |
| 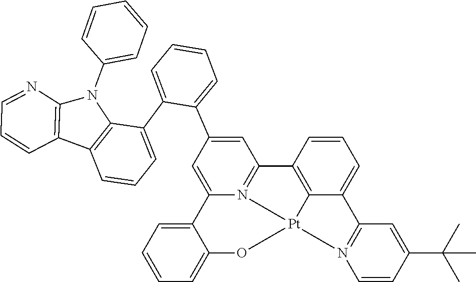 | 29 |
| 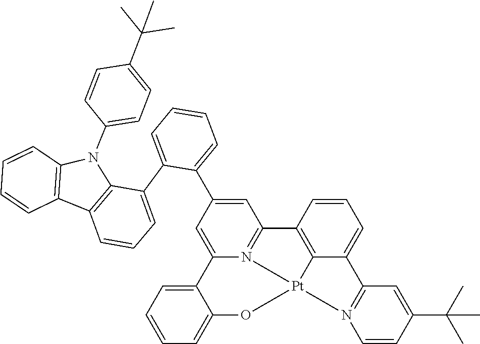 | 30 |
| 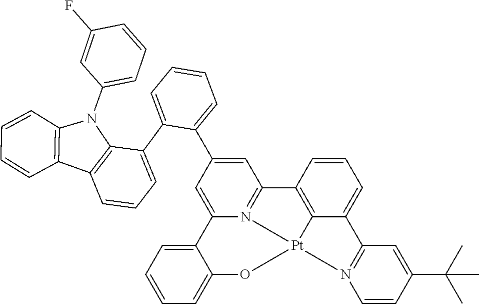 | 31 |
| 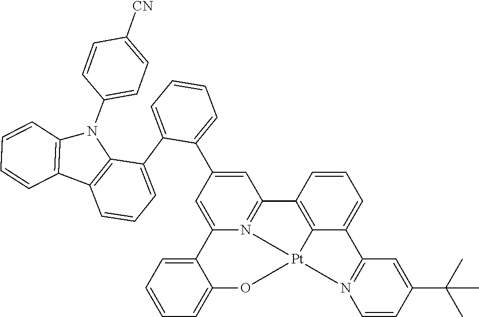 | 32 |
| 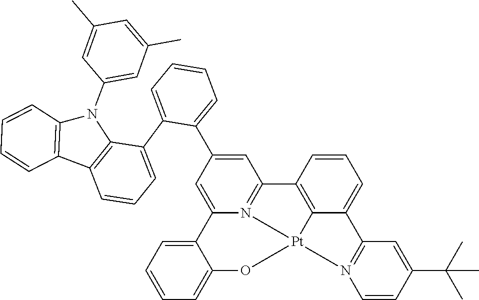 | 33 |
| 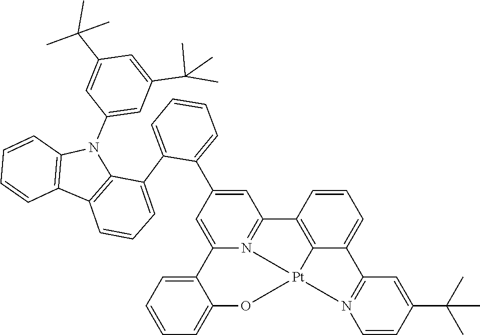 | 34 |
| 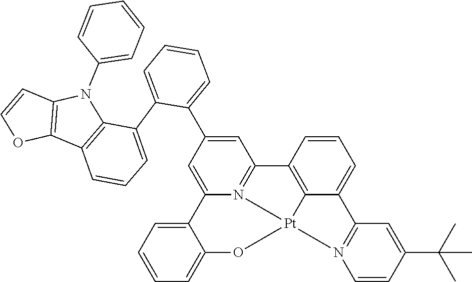 | 35 |
| 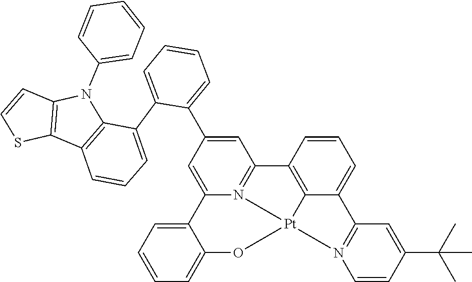 | 36 |
| 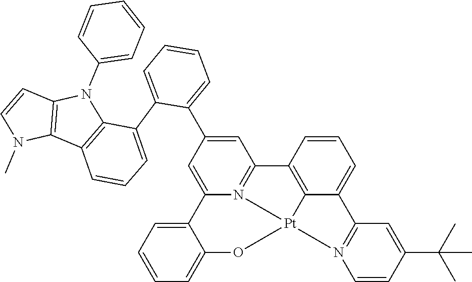 | 37 |
| 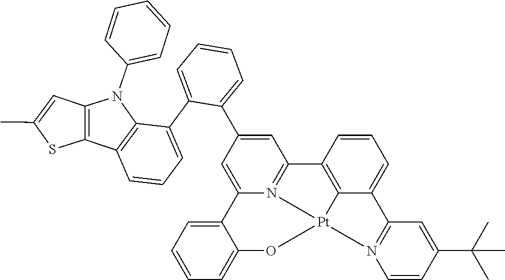 | 38 |
| 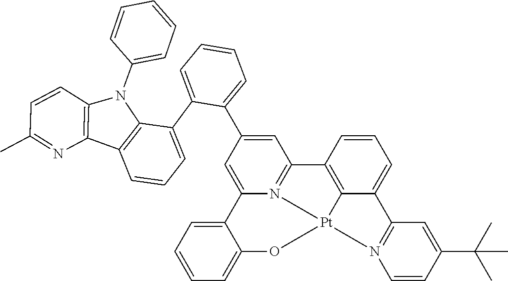 | 39 |
| 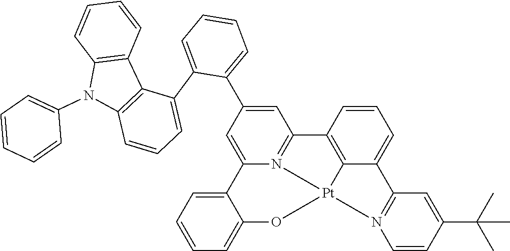 | 40 |
| 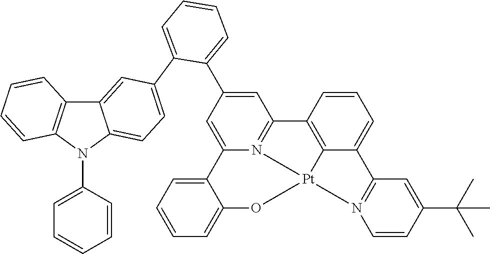 | 41 |
| 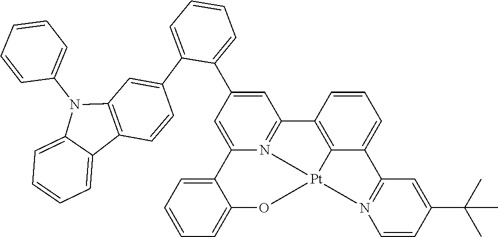 | 42 |
| 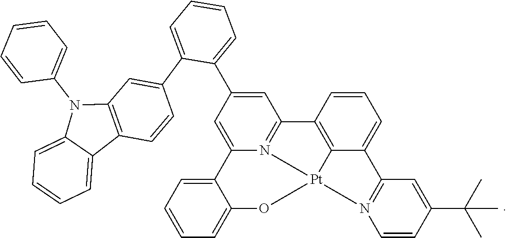 | 43 |

8. A precursor of the platinum complex according to any one of claims 1-6, namely, a ligand, having a structural formula below: 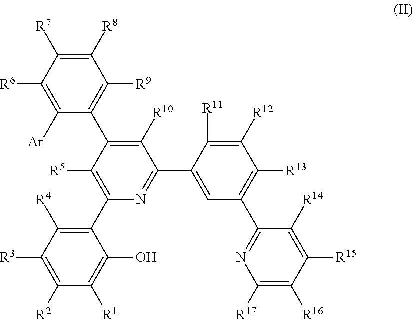
wherein R¹ to R¹⁵ and Ar are defined the same as claims 1-6.

9. Application of the platinum complex according to any one of claims 1-7 in an organic light-emitting diode, an organic thin film transistor, an organic photovoltaic device, a light-emitting electrochemical cell, or a chemical sensor.

10. An organic light-emitting diode, comprising a cathode, an anode and an organic layer, wherein the organic layer comprises one or more layers of a hole injection layer, a hole transport layer, a light-emitting layer, a hole blocking layer, an electron injection layer and an electron transport layer, and the organic layer contains the platinum complex according to any one of claims 1-7.

11. The organic light-emitting diode according to claim 10, wherein the platinum complex according to any one of claims 1-7 is located in the light-emitting layer.
